(19) United States
(12) Patent Application Publication
(10) Pub. No.: US 2014/0049933 A1
(43) Pub. Date: Feb. 20, 2014

(54) DETACHABLE COMPONENTS FOR SPACE-LIMITED APPLICATIONS THROUGH MICRO AND NANOTECHNOLOGY (DECAL-MNT)

(71) Applicants: Hans-Heinrich Gatzen, Isernhagen (DE); Tim Griesbach, Muhlacker (DE)

(72) Inventors: Hans-Heinrich Gatzen, Isernhagen (DE); Tim Griesbach, Muhlacker (DE)

(73) Assignee: HARTING KGAA, Espelkamp (DE)

(21) Appl. No.: 14/000,674

(22) PCT Filed: Feb. 24, 2012
(86) PCT No.: PCT/EP12/53147

§ 371 Date: Oct. 31, 2013

(30) Foreign Application Priority Data
Feb. 25, 2011 (DE) 10 2011 004 782.4

(51) Int. Cl. H05K 1/02; H05K 3/30

(52) U.S. Cl. CPC H05K 1/0271; H05K 3/303
USPC 361/807; 29/834

(57) ABSTRACT

The invention relates to space-saving micro- and nano-components and to methods for producing same. The components are characterized in that they do not comprise a rigid substrate having a considerable thickness. The mechanical stresses, which result in deformations and/or warpage within a component, are compensated by means of a mechanically stress-compensated design and/or by means of active mechanical stress compensation by depositing suitable stress compensation layers such that there is no need for relatively thick substrates. Thus, the overall thickness of the components is decreased and the integration options thereof in technical systems are improved. In addition, the field of application of such components is expanded.

The present invention relates to the production of detachable components for space-limited applications through micro and nanotechnology and electronics (DECAL-MNT).

The micro and nanosystem technology includes the design, production, and application of miniaturized technical systems, with their elements and components showing structural dimensions in the micrometer and nanometer range. Mircosystems consist of several components, which in turn comprise functional and structural elements. Here, a functional element of a component may show several layers, which in the following are also called the sandwich structure of a component. A microsystem may represent, e.g., an airbag triggering system, antenna system, intelligent sensor system, micro-engine, micro-analysis system, or a light modulator. The components may, e.g., be based on micro-mechanic, micro-electronic, micro-fluidic, or micro-optic [concepts] in order to perform, e.g., sensory, actuary, transmission, storage, or signal processing functions. The functional and form elements may represent, e.g., bending bars, membranes, stops, bearings, channels, metallizations, passivations, Piezo-resistances, heating resistors, and conductors. The use of the term “component” includes all micro and nanosystems, which show both non-electric as well as electric components, particularly micro-electronic components, also including construction elements, which represent preliminary stages of the components to be ultimately generated, with the minimum dimensions not being limited to the micrometer range but also including the nanometer range.

The production of micro-structures occurs by applying several different material layers via several different processing steps. The term “material layer” comprises all layers used temporarily such as e.g., a sacrificial layer, or permanently during the production of a component. The material layers show different physical characteristics, particularly they are characterized in different thermal expansion coefficients. The production of a component by applying several material layers usually occurs at a temperature above room temperature so that a subsequent temperature change leads to undesired mechanic stress, particularly tensile stress and/or pressure. This then leads to a deformation and/or warping of the individual material layers of the component. Therefore, the mechanic stress can negatively influence the adhesion between the individual material layers and result in separation, shifting, or destruction of the component. The above-mentioned effects compromise the functionality of the micro-structure and can render it useless, partially or entirely.

In prior art, it is primarily ensured that the individual material layers of a component strongly adhere to each other so that the resulting mechanic stress is compensated by a stiff substrate, which serves as the structural element and usually represents the wafer. The term “substrate” comprises all additional elements to uphold a predetermined form and/or to compensate mechanic stress. However, a substrate and/or a waver usually shows a considerable material strength and/or material thickness (e.g., 4-inch wafer: 525 μm), which requires a subsequent material reduction via cutting processes, etching, or a combination thereof, in order to this way yield a thinned wafer (e.g., thinned 4-inch wafer: 50 μm). The subsequent material reduction to increase the degree of miniaturization requires increased expenses and costs, which have negative economic consequences. Furthermore, usually no complete wafer reduction can be performed so that the degree of miniaturization is reduced. Accordingly micro-components or nanocomponents are separated to the wafer level after the production. This occurs most frequently by abrasive cutting. The components separated in this fashion are also called chips. Expensive assembly and connection technology is required in order to integrate micro-components or nanocomponents into a system. The assembly technology serves here primarily for the mechanic connection of the individual component to a carrier. This carrier can here represent a housing part, to which the component is connected by way of bonding, but also directly a circuit board on which the component is assembled without any housing. Here, the connection technology serves for generating the electric connections required for the electric or electronic system integration of the component. For this purpose, the component shows contact spots and/or contact sections at its periphery. For example a connection is generated by way of welding micro-wires between the contact spots of the component and the contact pins of the housing. They are then soldered, for example in a circuit board, of the next higher component within the system integration. Another method is to provide the individual components with small balls of solder at the contact spots, and thereby solder it to the component side and thus also the contact spots downwards directly on the contacts of a carrier. Due to the inversion of the component occurring here, this approach is called flip-chip technology. Here, not only an electric connection is formed between the contacts by this soldering connection but also a mechanic one.

From DE 19851967A1 a micro-reflector is known with a permanently arched membrane induced by mechanic stress. The arching of the membrane is achieved by applying a layer subjected to tensile stress on a monolithic membrane base body or a doping with foreign atoms showing different atomic radii.

From “IEEE Journal of Microelectromechanical Systems, Vol. 9, No. 4, December 2000” the publication “A New Technique for Producing Large-Area As-Deposited Zero-Stress LPVCD Polysilicon Films: The MultiPoly Process” is known, which relates to regulation and elimination of remaining stress and tension gradients in order to improve components. Here, layers with tensile stress and pressure are applied alternating.

A contact spring arrangement is known from DE 101 62 983 A1, in which a unilaterally fixed contact spring is arranged on a substrate, which is made from a semiconductor material showing a stress gradient causing a permanent curvature of the contact spring. The stress gradient in the semiconductor material is caused by two differently mechanically stressed semiconductor layers connected to each other.

The combination of physical vapor deposition (PVD) and chemical vapor deposition (CVP) is known from DE 60 2004 010 729 T2.

Methods are known from US 2002/0014673 A1 for the production of integrated circuits on flexible membranes, with the methods not using a semiconductor substrate as the first layer.

Micro-optic elements are known from DE 10 2006 057 568 A1 including a substrate and a method for the production of the above-mentioned elements using sacrificial layers.

The use of low radiation frequencies is known from U.S. Pat. No. 6,098,568 for the regulation of ion energy during the bombardment of substrates for a better control of mechanic stress.

None of the above-stated references of prior art described a method for the production of mechanically stress-compensated components. Furthermore, none of the above-mentioned references described an effective mechanically stress-compensated component.

The objective of the invention is to find a solution in order to at least reduce one of the above-mentioned disadvantages. In particular, a solution shall be suggested for the production of detachable and space-saving microcomponents and nanocomponents.

A component is suggested according to claim 1 in order to attain this objective according to the invention. The component according to the invention shows a thickness from approximately 1 to 50 μm and is essentially mechanically stress-compensated so that any warping or folding is prevented. Due to the mechanic stress compensation of the component, no stiff element is used, like for example a substrate (a wafer, a structural element, or a thinned substrate) in order to prevent warping or folds. Waiving a stiff substrate, which shows a considerable thickness, leads to the realization of a component with a low structural height and/or thickness.

According to another aspect of the present invention the component shows at least one stress compensation layer with a predetermined mechanic stress, so that the stress compensation layer at least partially compensates any mechanic stress of the component. Here, when mechanic stress of the component is given, compensation of the existing tensions and/or pressures is achieved via mechanic stress compensation layers such that any warping or folding is prevented. Thin components, which omit a wafer as the stiff substrate, are particularly susceptible to warping, in spite of their considerably smaller dimension in reference to a complete wafer. However, it is desirable that the components separated from the wafer are flat and unwarped. Here, the component may also show several stress compensation layers. In this case several stress compensation layers are deposited during the production of the component so that said component is subjected to continuous mechanic stress compensation. Here, a layer deposited in a suitable fashion of the layer structures required for the function of the component may also serve as a stress compensation layer. This way, the stress compensation layers may be used between the layer structures of the component. The deposition of a stress compensation layer with a predetermined mechanic stress occurs via various deposition processes, particularly by chemical vapor deposition (CVD) and physical vapor deposition (PVD). The CVD methods may occur at atmospheric pressure (APCVD), reduced pressure (RPCVD), as well as plasma-enhanced (PECVD). The PVD methods may occur via thermal processes or sputtering, particularly by ion beam sputtering or plasma sputtering.

According to one option of the present invention the component comprises at least one carrier layer, particularly made from epoxy resin. The carrier layer, also in the form of a carrier film, which may be provided particularly made from plastic, provides the component with a self-supporting feature. Therefore the carrier layer allows for mounting the component at a desired position. Here, the use of alternative materials of the carrier layer with smaller dimensions is increased, particularly with a lower thickness, because these carrier layers no longer serve to compensate existing mechanic stress of the component. Particularly suitable as a carrier layer and/or carrier film is, e.g., epoxy resin with the identification SU-8™, which can be structured by way of photo-lithography.

In another preferred embodiment of the component according to the invention the component comprises at least a first embedding layer. Here the layer structures of the component are embedded and thus integrated in the first embedding layer.

According to one option of the present invention, the component shows at least one second embedding layer. The second embedding layer serves to embed passages and the contacting section so that they are integrated in the second embedding layer.

In another preferred embodiment of the component according to the invention the component comprises at least one contacting section. It allows generating a contact with other components and parts of the system the component is allocated to and the transmission and/or receipt of signals. The side of the component comprising the contacting sections is applied on a carrier for system integration. This carrier also comprises contacting sections, which show a mirror image in reference to the contacting sections of the component. The assembly occurs such that the contacting sections of the component and the carrier are in contact. The connection of the component to its carrier preferably occurs by way of adhesion, with the adhesive here being required to be electrically conductive in the area of the contacting sections. Preferably stiff circuit boards, flexible flat cables, or molded interconnect devices (MID), three-dimensional carrier structures provided with conductors serve as carriers, as used for example in mobile phones. Additionally it is advantageous when the component shows a carrier layer. In this case the contacting sections are integrated in the carrier layer. This arrangement is further advantageous when after separation, the micro-component or the nanocomponent is transferred to a handling layer. In this case the fastening of the component on the carrier also occurs preferably via adhesion, with in the area of the contacting sections the connection must be electrically conductive.

According to one option of the present invention the component comprises at least one penetrating contacting. Here, the penetrating contacting serves to establish a connection between the signal generating and/or signal receiving part of the component and the contacting area, particularly the penetrating contacting is used to establish a connection between the component section generating electric signals and the contacting section for the communication with other components or systems.

According to another aspect of the present invention the component is designed to perform sensor and/or actuator tasks. The components may be designed and produced to perform various tasks so that they are able to execute a multitude of tasks. These components are ultrathin and include no substrate so that their low thickness facilitates the integration in technical systems. For example, on a flexible flat cable a plurality of temperature sensors according to the present invention can be applied and, this way, temperature measurements can be performed at many different positions. Further, expansion measuring sensors can be applied at very different positions directly at the structures to be measured and connected via a flexible flat cable extending over the components to each other or to a processing system. In case of local data networks here according to the invention, antennas can be applied directly on the housing.

According to another aspect of the present invention the component is designed for signal transmission and/or for signal reception. These components are also ultrathin, show no substrate, and can be integrated in technical systems.

According to a preferred embodiment of the present invention a component system is suggested comprising at least two components according to the above-stated embodiments. The component system comprises identical or different components, which are intended to perform sensor or actuator functions. This way, different component systems can be assembled, which can perform a certain combination of tasks. The space-saving feature of the components and the production methods in microsystem and nanosystem technology can be used advantageously for the production of these component systems so that in one production process several different components can be produced simultaneously for the execution of various tasks and thus a component system develops in which the individual components can be partially connected to each other and can communicate.

According to another option of the present invention a component system is suggested comprising at least two components according to the above-described embodiments for signal transmission and/or signal reception. The component system is assembled from identical or different components, which are provided for signal transmission and/or signal reception. Here, different component systems can also be connected to each other so that complex tasks can be executed by the optional combination of the individual component systems.

According to one aspect of the present invention, a method is suggested for the production of a component or component system without substrates showing a thickness from approximately 1 to 50 μm on a sacrificial layer or a carrier layer or a carrier layer located on a sacrificial layer. The method comprises several steps. The first step is the layered formation of the component or the modular system via various physical and/or chemical processes. The formation of the individual layers occurs such that each individual layer of the component or the modular system shows a predetermined mechanic stress, with the mechanic stress of the individual layers of the component or the component system essentially compensate (each other) in order to prevent any warping or folding. Here, the component or the modular system is formed on a sacrificial layer, a carrier layer, or a carrier layer applied on a sacrificial layer. After the production of the component or the component system a given sacrificial layer, if so used, can be removed via physical and/or chemical methods. Here, chemical and physical processes are used to remove material layers, such as dry etching methods and wet chemical etching methods. After the removal of an existing sacrificial layer the component or the component system can be removed and subsequently placed at a desired position. According to this method components or component systems can be produced with or without any carrier layers.

According to another aspect of the present invention a method is suggested for the production of a non-substrate component or component system without substrates showing a thickness from approximately 1 to 50 μm on a sacrificial layer or a carrier layer or a carrier layer located on a sacrificial layer. The method includes several steps and is therefore characterized in that the first step of the above-mentioned method is replaced by a combination of a layer construction of the component or the component system via different physical and/or chemical processes and the deposition of a voltage compensation layer via CVD and/or PVD at the component or the component system or within the layer structure of the component for at least a partial compensation of mechanic stress of the component or the component system in order to prevent any warping or folding. Here, by the deposition of at least one stress compensation layer at the component or the component system or within the layer structure of the component the mechanic stress caused by temperature changes is compensated. The parameters for depositing a stress compensation layer with a predetermined mechanic stress can be determined by way of calculation, simulation, or experimental embodiments. Subsequently the sacrificial layer is removed, if present, using a physical and/or chemical method so that the component or the component system is ultimately removed. According to this method both, the components or component systems, can be produced with or without a carrier layer, with their mechanical stress being compensated by the deposited stress compensation layers.

According to another aspect of the present invention, a method is suggested for the production of a component or component system without a substrate showing a thickness from approximately 1 to 50 μm on a sacrificial layer or a carrier layer or a carrier layer located on a sacrificial layer. The method comprises several steps and is characterized in that after the layer production of the component or the component system, via different physical and/or chemical processes or after a combination with the above-mentioned step for depositing a stress compensation layer via CVD and/or PVD at the component or the component system or within the layered structure of the component at least one auxiliary layer is applied at the component or the component system. Here, an auxiliary layer is understood for example as a handling layer, adhesive layer, or protective layer, which may also be composed in various combinations and applied at the component. The handling layer temporarily or permanently adheres to the component and serves to remove the component so that the component can be placed at a different position. Furthermore, via an auxiliary layer and/or a handling layer several components or component systems can be adhered side-by-side so that a flexible film is provided comprising several components or component systems. The handling layer may show various embodiments and materials and be combined variably.

In another preferred method according to the present invention, after the repositioning of the component or the component system, the removal of at least one auxiliary layer occurs. Furthermore it is possible, using a multi-layer handling layer, to remove a layer of the handling layer at least sectionally, with here the underlying layer perhaps showing adhesive features, for example in order to adhere the component at the intended position. Here, by a suitable selection and combination of auxiliary layers, which may be produced from different materials, an application of the component or the component system can be realized like a decal.

In another preferred method according to the present invention, the deposition of the stress compensation layer occurs via plasma-enhanced chemical deposition from the vapor phase at least at a deposition frequency, particularly two deposition frequencies so that the mechanic stress of the stress compensation layer can be adjusted via said deposition frequency. Here, preferably inorganic insulation layers are used, e.g., Si₃N₄. When selecting the higher frequency the deposited layer shows tensile stress and when selecting the lower frequency the central free path length of the ions of the plasma gas increases such that they bombard the developing material layer and thus generate pressure. By the combination of two partial layers with tensile stress being given in one and pressure in the other one, in the overall layer any tensile stress or pressure can be largely adjusted to an arbitrary extent.

According to a preferred embodiment of the present invention the production of a component or a component system is suggested according to one of the above-mentioned methods. In this embodiment, stress-compensated components or component systems are produced that are particularly space-saving and can be integrated in different technical systems.

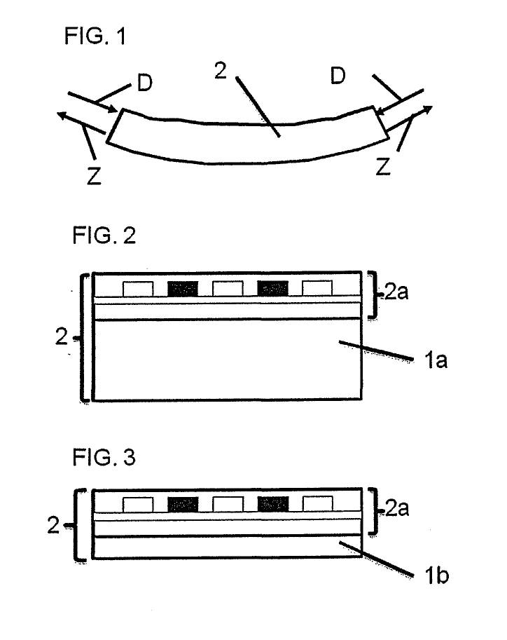

In the following some exemplary embodiments and principle production steps of the components according to the invention are described as examples based on the FIGS. 1 to 18 showing the essential processing steps.

FIG. 1 shows schematically the warping of a component (2) due to existing pressures and tensions (D, Z).

FIG. 2 shows schematically a component (2) and its layered structures (2a) on a not-thinned substrate (1a).

FIG. 3 shows schematically a component (2) and its layered structure (2a) with a thinned substrate (1b) according to prior art.

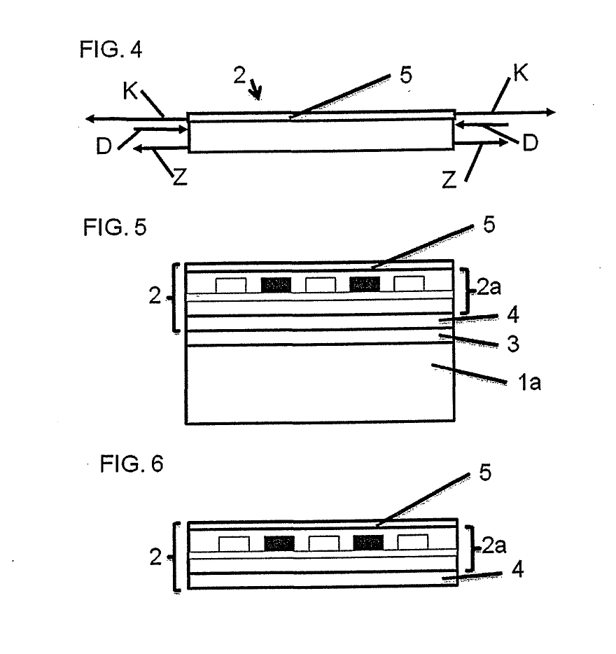

FIG. 4 shows schematically a component (2), which comprises a deposited stress compensation layer (5) with a compensation stress (K) for compensating the existing pressures and tensions (D, Z) of the component (2).

FIG. 5 shows schematically a detachable component (2) which comprises a stress compensation layer (5) and a carrier layer (4).

FIG. 6 shows schematically the detachable component (2) of FIG. 5 after separation.

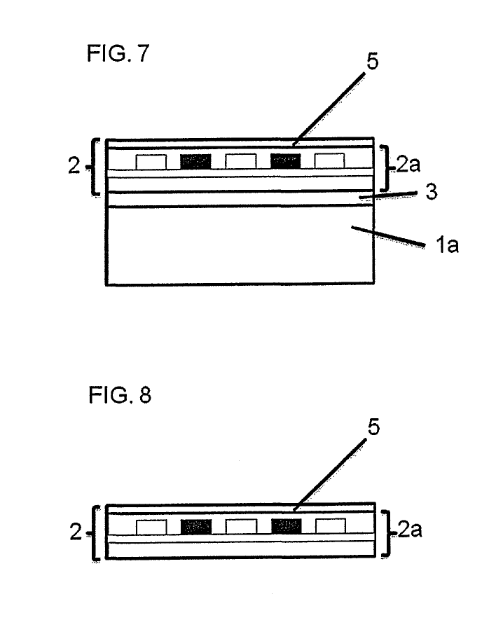

FIG. 7 shows schematically a detachable component (2) comprising a stress compensation layer (5) and no carrier layer (4).

FIG. 8 shows schematically the detachable component of FIG. 7 after separation.

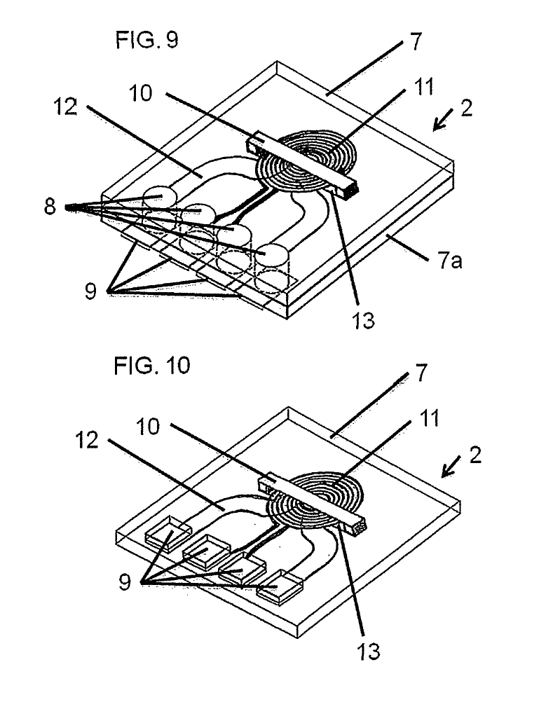

FIG. 9 shows schematically a stress compensated detached component (2) according to the invention with a first embedding layer (7) and a second embedding layer (7a).

FIG. 10 shows schematically a stress compensated component (2) with a first embedding layer (7).

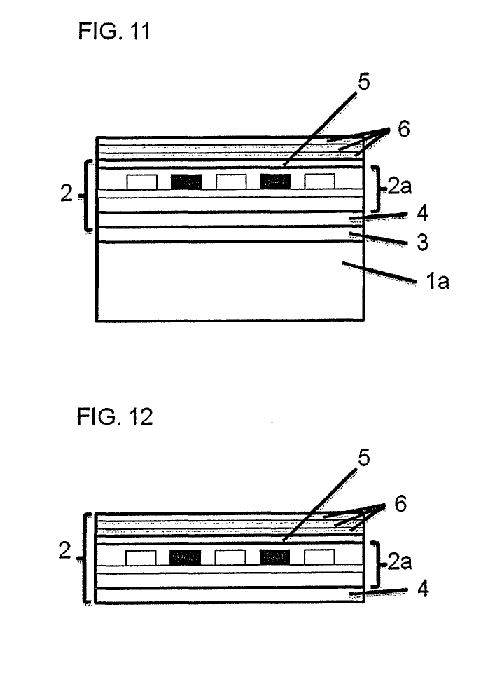

FIG. 11 shows schematically a detachable component (2) comprising a carrier layer (4) and several auxiliary layers (6).

FIG. 12 shows the component (2) according to the invention of FIG. 11 after the separation from the wafer and/or substrate (1a).

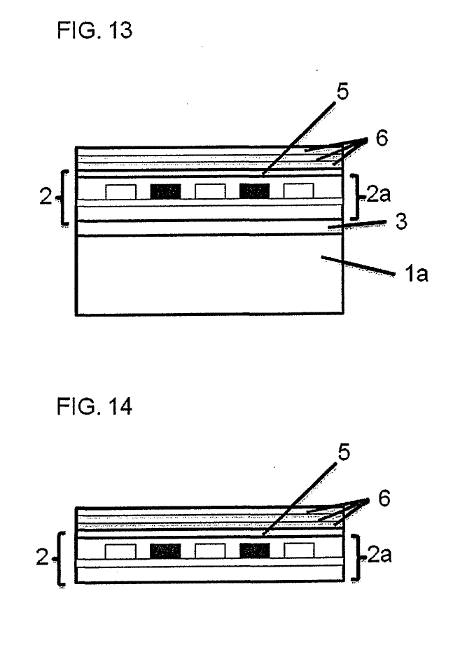

FIG. 13 shows schematically a detachable component (2) according to the invention, which comprises several auxiliary layers (6) and no carrier layer (4).

FIG. 14 shows the component (2) according to the invention of FIG. 13 after the separation from the wafer and/or substrate (1a).

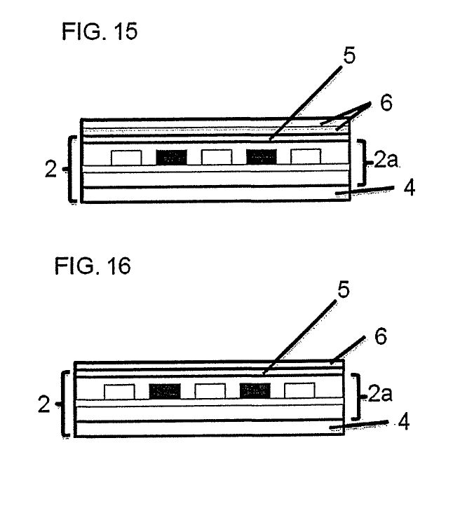

FIG. 15 shows the component (2) according to the invention of FIG. 12 after the removal of the uppermost auxiliary layer (6).

FIG. 16 shows the component (2) according to the invention of FIG. 15 after the removal of the uppermost auxiliary layer (6).

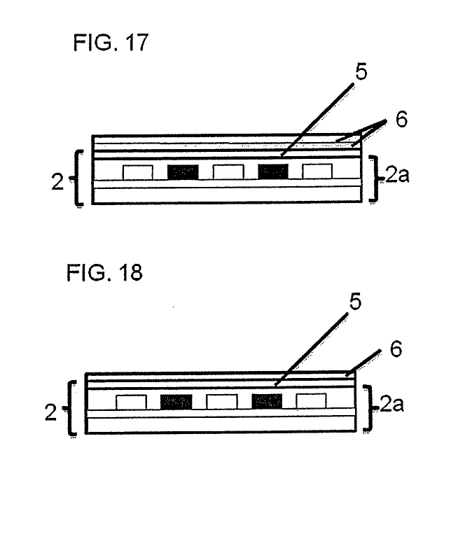

FIG. 17 shows the component (2) according to the invention of FIG. 14 after the removal of the uppermost auxiliary layer (6).

FIG. 18 shows the component (2) according to the invention of FIG. 17 after the removal of the uppermost auxiliary layer (6).

FIG. 1 shows as an example a loose component (2), which due to its pressure (D) and tensile stress (Z) is warped and is provided in an arched form. FIG. 2 shows how the above-mentioned curvature is prevented according to prior art by the production of the component (2) on a stiff and thick wafer and/or substrate (1a). Conditional to sufficient adherence of the individual layers of the layer system of the component and/or the layer structure of the component (2a), the existing pressure and tensile stress (D, Z) are compensated by the stiff wafer and/or substrate (1a) so that the component (2) shows no warping. According to prior art, as shown in FIG. 3, in order to reduce the thickness of the component (2) the substrate and/or the wafer (1a) are subsequently thinned via cutting and/or etching so that a thinned substrate (1b) is provided, which reduces the thickness of the overall component (2).

FIG. 4 shows schematically the use of the stress compensation layer (5) according to the invention for the compensation of mechanic stress of the component (2). Here, existing pressure and tensile stress (D, Z) of the component (2) are essentially compensated by the deposited stress compensation layer (5) with a mechanic compensation stress (K).

FIG. 5 shows a component (2) according to the invention, which is produced on a carrier layer (4) provided on a sacrificial layer (3) and shows a stress compensation layer (5). Here, the carrier layer (4) serves to apply and position the component (2) on an arbitrary surface. The mechanic stress of the component (2) is essentially compensated via the stress compensation layer (4) so that a thin carrier layer (4) is used with a thickness of approximately 5 μm. Due to the fact that the component (2) shows a deposited stress compensation layer (5) and only a thin carrier layer (4) is used the overall thickness of the component (2) is considerably reduced. The above-mentioned component (2) with a layer structure (2a) is illustrated schematically in FIG. 6 showing a stress compensation layer (5) and a thin carrier layer (4).

FIG. 7 shows a component (2) according to the invention, which is produced directly on a sacrificial layer (3) and comprises a stress compensation layer (5). The deposited stress compensation layer (5) essentially compensates the mechanic stress of the component (2) and/or the structural layer of the component (2a) so that after the subsequent removal of the sacrificial layer (3), as shown in FIG. 8, a very thin component (2) is provided with an overall thickness from approximately 1 to 50 μm. This embodiment allows the application of the component (2) on any arbitrary underground.

FIG. 9 shows a modular component (2), built in a stress compensated fashion, according to one aspect of the present invention. The component (2) illustrated in FIG. 9 is a sensor, which comprises various modular components integrated in a first embedding layer (7): penetrating contacting (8), flux guidance (10), sensor coil (11), exciter coil (12), and magneto-elastic flux guidance (13). A second embedding layer (7a) serves to integrate the penetrating contacting (8) and the contacting sections (9). The overall thickness of the sensor is considerably reduced by the stress-compensated design.

FIG. 10 shows a modular component (2), built in a stress-compensated fashion, according to another aspect of the present invention. The component (2) shown in FIG. 10 is a sensor comprising various modular components integrated in a first embedding layer (7): contacting section (9), flux guidance (10), sensor coil (11), exciter coil (12), and magneto-elastic flux guidance (13). Here the component (2) shows no second embedding layer (7a). The sensor can be applied and positioned on any arbitrary underground.

FIG. 11 shows the layer structure of a component (2a), which is produced on a sacrificial layer (3), which in turn is applied on a carrier layer (4), and shows a stress compensation layer (5). Additionally the component shows several auxiliary layers (6), which serve for handling, adhering, and protecting the component. According to the invention at least one auxiliary layer (6) is used, with one auxiliary layer (6) can be combined, when necessary, with additional auxiliary layers (6). Therefore the individual auxiliary layers (6) can be mounted successively or together at the component (2). The combined use of auxiliary layers (6) allows the removal and the application of the component (2) like a decal. Accordingly the uppermost auxiliary layer (6) serves for handling and/or removing the component so that it can be removed after the positioning of the component (2).

FIG. 12 shows the component (2) according to the invention after the removal of the sacrificial layer (3) so that the component (2) of FIG. 11 is provided on a carrier layer (4).

FIG. 13 shows a layer component structure (2a), which is produced on a sacrificial layer (3) and comprises a stress compensation layer (5). Additionally the component shows several auxiliary layers (6) serving for handling, adhering, and protecting the component and used for various tasks, as described above. Accordingly, in the embodiment provided in FIG. 14 a lower overall thickness of the component (2) can be achieved, because no carrier layer (4) is used so that a component (2) is provided like a decal. Accordingly it is provided that at least one layer of the handling film can be removed at least sectionally. Here, at least one layer of the handling layer is removed after the removal and positioning of the component so that the surface of the component is exposed. Additionally, in an appropriate multi-layer handling layer the uppermost layer can be removed, which fulfills protective functions.

FIG. 15 shows the component (2) of FIG. 12 according to the invention after the uppermost auxiliary layer (6) has been removed. Additionally FIG. 16 shows the component of FIG. 15 after the removal of another auxiliary layer (6).

FIG. 17 shows the layer structure of the component (2a) according to the invention of FIG. 14 after the uppermost auxiliary layer (6) has been removed. Additionally, FIG. 18 shows the layer structure of the component (2a) of FIG. 15 after the removal of another auxiliary layer (6).

1. A component (2) with a thickness from approximately 1 to 50 μm,
with the component (2) being without a substrate and comprising at least one stress compensation layer (5) with a predetermined mechanic stress for compensating existing tensile stress and pressures in order to prevent warping or folding.

2. A component (2) according to claim 1,
with the component (2) comprising at least one carrier layer (4), particularly made from plastic.

3. A component (2) according to claim 1,
with the component (2) comprising at least a first embedding layer (7).

4. A component (2) according to claim 1,
with the component (2) comprising at least a second embedding layer (7a).

5. A component (2) according to claim 1,
with the component (2) comprising at least one contacting section (9).

6. A component (2) according to claim 1,
with the component (2) comprising at least one penetrating contacting (8).

7. A component (2) according to claim 1,
with the component (2) being embodied to perform sensor and/or actuator tasks.

8. A component (2) according to claim 1,
with the component (2) being embodied for signal transmission and/or signal reception.

9. A component system comprising at least one component (2) according to claim 1,
with the component system being embodied to perform sensor and/or actuator tasks.

10. A component system comprising at least one component (2) according to claim 1,
with the component system being embodied for signal transmission and/or signal reception.

11. A method for the production of a component (2) or component system without substrates showing a thickness from approximately 1 to 50 μm on a sacrificial layer (3) or a carrier layer (4) or a carrier layer (4) located on a sacrificial layer (3),
with the method comprising the following steps:
a) a layer structure of a component (2) or the component system via various physical and/or chemical processes, with the construction occurring such that each individual layer of the component (2) of the component system shows a predetermined mechanic stress, with the mechanic stress of the individual layers of the component (2) or the component system essentially compensate each other in order to prevent any warping or folding,
b) a physical and/or chemical removal of the sacrificial layer (3), if provided,
c) the removal of the component (2) or the component system, and
d) the repositioning of the component (2) or the component system.

12. A method according to claim 11,
with the first step being replaced by a combination of the following steps:
e) a layer construction of the component (2) or the component system via different physical and/or chemical processes, and
f) the deposition of a stress compensation layer (5) via CVD and/or PVD at a component (2) or the component system or within the layer structure of the component (2a) for at least a partial compensation of mechanic stress of the component (2) or the component system in order to prevent warping or folding.

13. A method according to claim 11, with after step a) or a combination of steps e) and f) the following step is performed:
g) applying at least one auxiliary layer (6).

14. A method according to claim 11,
with after the step d) the following step being performed:
h) removal of at least one auxiliary layer (6).

15. A method according to claim 12,
with the deposition of the stress compensation layer (5) occurring via plasma-enhanced chemical deposition from the vapor phase at least at a deposition frequency, particularly two deposition frequencies, for adjusting the mechanic stress of the stress compensation layer (5).

16. A component (2) or component system produced according to claim 11.
